(19) United States
(12) Patent Application Publication
(10) Pub. No.: US 2025/0372498 A1
(43) Pub. Date: Dec. 4, 2025

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: EUI JEONG KANG, Yongin-si (KR); CHANGWOO WON, Yongin-si (KR); SEOUNGBUM PYOUN, Yongin-si (KR)

(21) Appl. No.: 19/077,467

(22) Filed: Mar. 12, 2025

(30) Foreign Application Priority Data
May 30, 2024 (KR) 10-2024-0070925

(51) Int. Cl. H01L 23/498; H01L 23/00; H01L 25/16

(52) U.S. Cl. CPC H01L 23/49838; H01L 24/29; H01L 25/167; H01L 2224/29006; H01L 2224/29028; H01L 2224/29191

(57) ABSTRACT

A display device that includes a substrate including a display area and a pad area disposed adjacent to a side of the display area; a driving chip disposed in the pad area in a first direction away from the side of the display area; a plurality of pad electrodes disposed in the pad area and arranged along a second direction perpendicular to the first direction; and a circuit board including a plurality of leading electrodes coupled to the plurality of pad electrodes, wherein a portion of the circuit board overlaps at least a portion of the pad area of the substrate.

### CROSS-REFERENCE TO RELATED APPLICATION(S)

This application claims priority under 35 U.S.C. § 119 to Korean Patent Application No. 10-2024-0070925, filed on May 30, 2024, in the Korean Intellectual Property Office (KIPO), the contents of which is herein incorporated by reference.

### TECHNICAL FIELD

Embodiments relate to a display device. More specifically, embodiments relate to the display device including a circuit board and an electronic device including the display device.

### DISCUSSION OF THE RELATED ART

As information technology develops, display devices continue to evolve, serving as the communication interface between users and information. The display device includes a display panel and a circuit board. The circuit board mis coupled to the display panel to provide various signals and voltages to the display panel necessary for driving the display panel.

### SUMMARY

A display device according to an embodiment of the present disclosure includes a substrate including a display area and a pad area disposed adjacent to a side of the display area; a driving chip disposed in the pad area in a first direction away from the side of the display area; a plurality of pad electrodes disposed in the pad area and arranged along a second direction perpendicular to the first direction; and a circuit board including a plurality of leading electrodes coupled to the plurality of pad electrodes, wherein a portion of the circuit board overlaps at least a portion of the pad area of the substrate.

A display device according to an embodiment of the present disclosure includes a substrate including a display area and a pad area disposed adjacent to a side of the display area; a first driving chip and a second driving chip disposed in the pad area in a first direction away from the side of the display area; a plurality of first pad electrodes disposed in the pad area adjacent to the first driving chip and arranged along a second direction perpendicular to the first direction; a plurality of second pad electrodes disposed in the pad area adjacent to the second driving chip and arranged along the second direction; and a first circuit board, wherein a portion of the first circuit board overlaps at least a portion of the pad area of the substrate and coupled to the first pad electrode.

An electronic device according to an embodiment of the present disclosure includes a processor; a memory having stored application programs for execution by the processor; a display device, and an user interface configured to sense user input via touch or cursor select of an icon presented on the display panel, wherein the processor is caused to execute one or more of the stored application programs upon receipt of the user input. The display device includes a substrate including a display area and a pad area disposed adjacent to a side of the display area; a driving chip disposed in the pad area in a first direction away from the side of the display area; a plurality of pad electrodes disposed in the pad area and arranged along a second direction perpendicular to the first direction; a circuit board, wherein a portion of the circuit board overlaps at least a portion of the pad area of the substrate and coupled to the pad electrode.

However, the effects of the present disclosure are not limited to the above effects, and may be expanded in various ways without departing from the spirit and scope of the present disclosure.

### BRIEF DESCRIPTION OF THE DRAWINGS

FIG. 1 is a plan view illustrating a display device according to an embodiment of the present disclosure.

FIG. 2 is a plan view illustrating a display panel and a circuit board of FIG. 1 before they are coupled.

FIG. 3 is a cross-sectional view taken along line I-I′ of FIG. 1.

FIG. 4 is an enlarged view illustrating area AA of FIG. 3.

FIG. 5 is a cross-sectional view taken along line II-II′ of FIG. 1.

FIG. 6 is a plan view illustrating a display device according to an embodiment of the present disclosure.

FIG. 7 is a plan view illustrating the display panel, first circuit boards, and a second circuit board of FIG. 6 before they are coupled

FIG. 8 is a cross-sectional view taken along line III-III′ of FIG. 6.

FIG. 9 is an enlarged view illustrating area BB of FIG. 8.

FIG. 10 is a cross-sectional view taken along line IV-IV of FIG. 6.

FIG. 11 is a plan view illustrating a display device according to an embodiment of the present disclosure.

FIG. 12 is a plan view illustrating the display panel the first circuit boards, and the second circuit board of FIG. 11 before they are coupled.

FIG. 13 is a plan view illustrating the first circuit board of FIG. 11 bent.

FIG. 14 is a cross-sectional view taken along line V-V of FIG. 13.

FIG. 15 is a plan view illustrating a display device according to an embodiment of the present disclosure.

FIG. 16 is a cross-sectional view taken along line IV-IV of FIG. 15.

FIG. 17 is a plan view illustrating a display device according to an embodiment of the present disclosure.

FIG. 18 is a plan view illustrating a display device according to an embodiment of the present disclosure.

FIG. 19 is a block diagram showing an electronic device according to embodiments of the present disclosure.

FIG. 20 are schematic diagrams showing an electronic device according to various embodiments.

### DETAILED DESCRIPTION OF THE EMBODIMENTS

Hereinafter, a display device and an electronic device including the same according to embodiments of the present disclosure will be described in more detail with reference to the attached drawings. The same reference numerals will be used for the same components in the drawings, and redundant descriptions of the same components will be omitted.

In display devices, a circuit board may be coupled to a display panel to supply the signals and voltages required for driving the display panel. During the process of coupling the circuit board to a pad area disposed on a substrate, a bonding tool may be employed.

To use the bonding tool, sufficient space is needed to apply it on the substrate without interfering with driving chips.

In an embodiment of the present disclosure, pad electrodes that are coupled to the circuit board might not be positioned directly below the driving chips in a plan view. Instead, the pad electrodes may be disposed on the left and/or right side of each driving chip.

This arrangement may create space on the left and/or right side of the driving chips for applying the bonding to the substrate, without the need for a separate space below the driving chips.

As a result, the width of the pad area may be reduced, which helps minimize the dead space in the display device. Moreover, the reduction in dead space may increase the visibility of the display device.

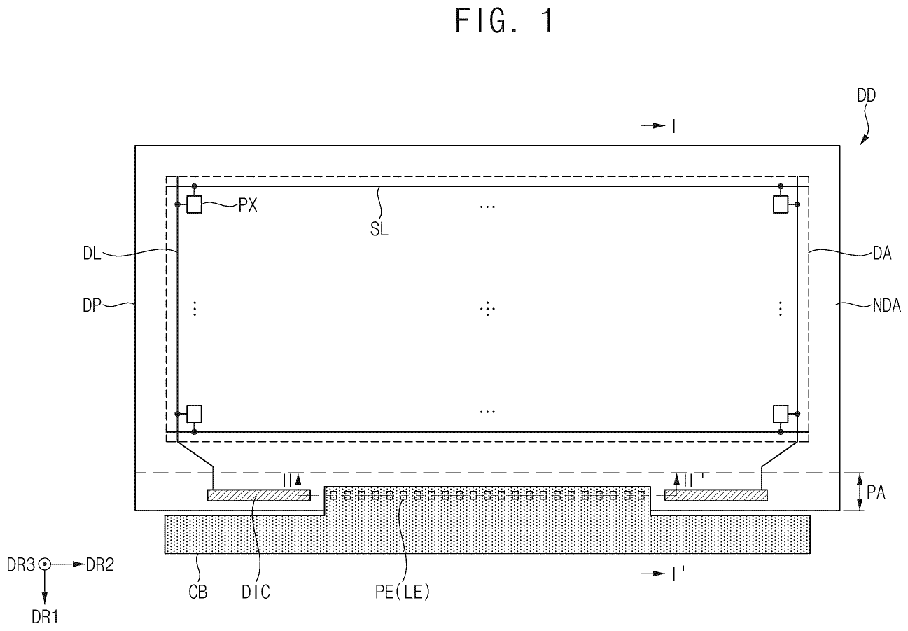

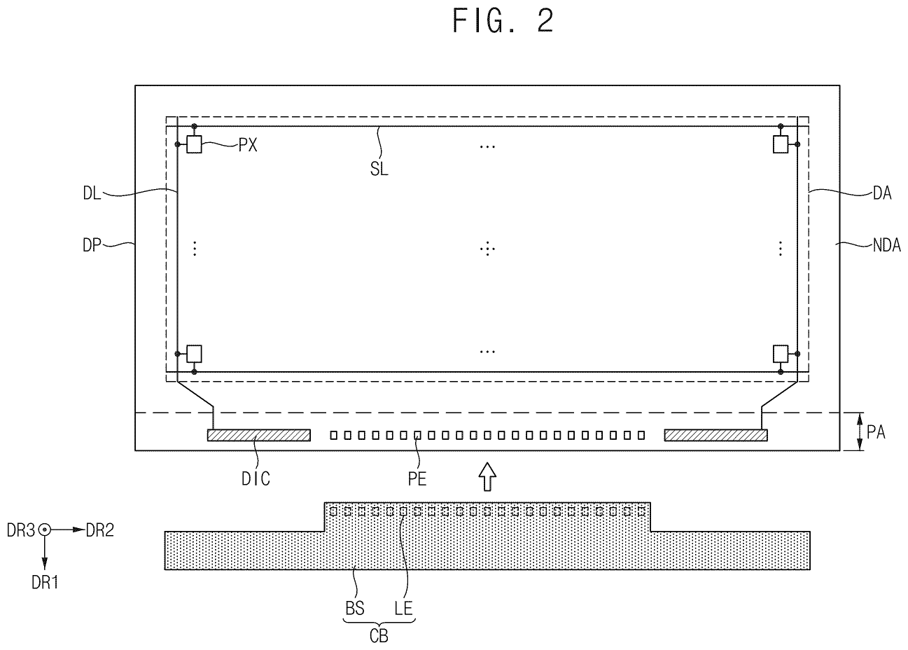

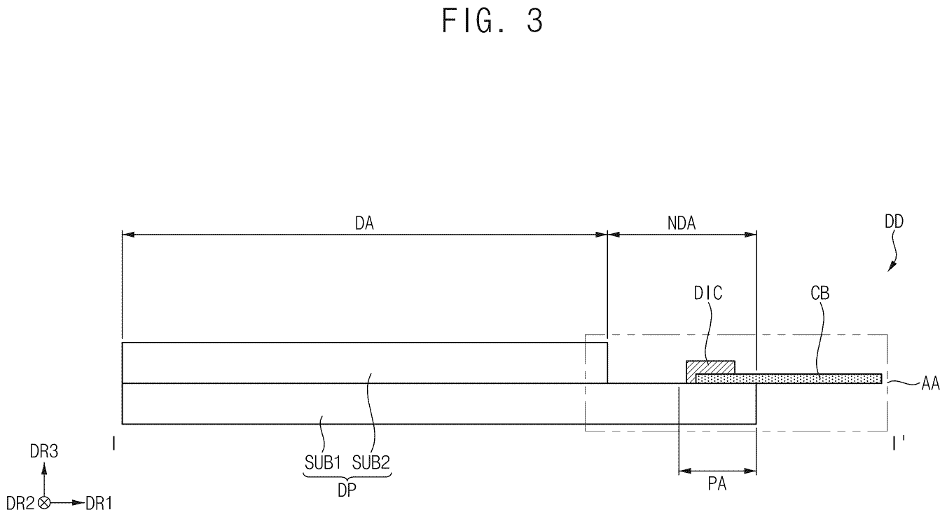

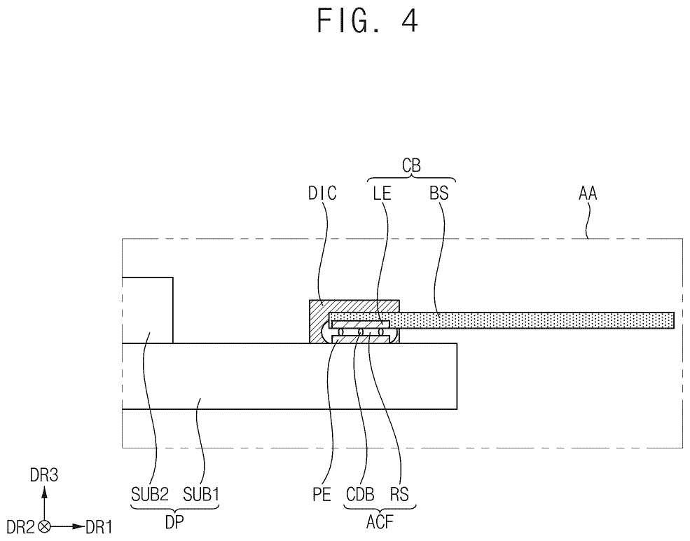

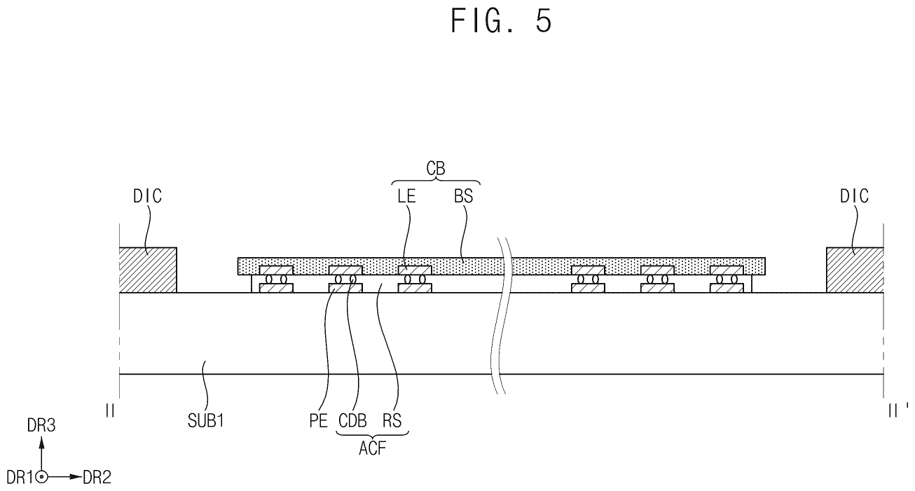

FIG. 1 is a plan view illustrating a display device according to an embodiment of the present disclosure. FIG. 2 is a plan view illustrating a display panel and a circuit board of FIG. 1 before they are coupled. FIG. 3 is a cross-sectional view taken along line I-T of FIG. 1. FIG. 4 is an enlarged view illustrating area AA of FIG. 3. FIG. 4 is an enlarged view illustrating area AA of FIG. 3. FIG. 5 is a cross-sectional view taken along line II-II′ of FIG. 1.

Referring to FIGS. 1 to 5, the display device DD according to an embodiment of the present disclosure may include a display panel DP, driving chips DIC, and a circuit board CB.

The display panel DP may include a display area DA and a non-display area NDA. The display area DA may be an area that can display an image by generating light or adjusting the transmittance of light supplied from an external light source. The non-display area NDA may be an area that does not display an image.

A plurality of pixels PX may be arranged in the display area DA. The plurality of pixels PX may be arranged in a matrix form along a first direction DR1 and a second direction DR2 perpendicular to the first direction DR1. Each of the plurality of pixels PX may emit light. As each of the plurality of pixels PX emits light, the display area DA may display the image. For example, the first direction DR1 and the second direction DR2 may define a plane, and the image may be displayed along a third direction DR3, which may be referred to as a normal direction of the plane.

The non-display area NDA may be located around the display area DA. For example, the non-display area NDA may surround the display area DA. A driving part may be located in the non-display area NDA. The driving part may provide signals and/or voltages to the plurality of pixels PX. For example, the driving part may include a scan driving part, a light emission driving part, a power supply voltage generating part, a timing controller, etc.

As illustrated in FIGS. 3 and 4, the display panel DP may include a first substrate SUB1 and a second substrate SUB2 disposed on the first substrate SUB1. The display panel DP may further include a sealing member that combines the first substrate SUB1 with the second substrate SUB2. For example, the sealing member may be disposed between the first substrate SUB1 and the second substrate SUB2.

The first substrate SUB1 may include pixels PX and a light emitting element disposed in each pixels PX. The first substrate SUB1 may be a display substrate that provides light necessary for displaying the image. In an embodiment of the present disclosure, the first substrate SUB1 may be a rigid substrate including glass, quartz, etc. In an embodiment of the present disclosure, the first substrate SUB1 may be a flexible substrate including soft glass, a polymer material, etc.

The second substrate SUB2 may face the first substrate SUB1. For example, the second substrate SUB2 may be disposed on an upper surface of the first substrate SUB1. For example, the second substrate SUB2 may be an encapsulation substrate disposed on the first substrate SUB1 to encapsulate the light emitting element. The second substrate SUB2 may prevent damage to the light emitting device from air or moisture. The second substrate SUB2 may include a transparent plate or a transparent film. For example, the second substrate SUB2 may include glass, quartz, etc.

The first substrate SUB1 may include the display area DA and the non-display area NDA. For example, the first substrate SUB1 may include the display area DA and the non-display area NDA, and accordingly, the display panel DP may include the display area DA and the non-display area NDA. The first substrate SUB1 may have a larger planar area than the second substrate SUB2. For example, the first substrate SUB1 may protrude further in the first direction DR1 from a side of the second substrate SUB2 extending along the second direction DR2 in the first direction DR1. The remaining sides of the first substrate SUB1 may be aligned with the remaining sides of the second substrate SUB2.

The non-display area NDA may include the pad area PA. The pad area PA may be located in the first direction DR1 from a side of the display area DA. For example, the pad area PA may have a shape protruding in the second direction DR2.

As shown in FIGS. 1 and 2, the display panel DP may further include scan lines SL and data lines DL. In an embodiment of the present disclosure, the scan lines SL may extend in the second direction DR2 and be arranged along the first direction DR1. The data lines DL may extend in the first direction DR1 and may be arranged along the second direction DR2.

Each of the pixels PX may be connected to at least one of the scan lines SL and at least one of the data lines DL. The scan lines SL may receive a scan signal from the scan driving part and transmit the scan signal to the pixels PX. A pixel PX to which a data voltage is supplied is selected by the scan signal, and the data voltage may be supplied to the selected pixel PX.

Each of the driving chips DIC may be disposed in the pad area PA on the display panel DP (e.g., first substrate SUB1). For example, the driving chips DIC may be disposed on the first substrate SUB1. For example, the driving chips DIC may be located in the first direction DR1 from the display area DA. The driving chips DIC may be disposed to be spaced apart from each other along the second direction DR2. The driving chips DIC may be electrically connected to at least one of the data lines DL extending from the display area DA. Each of the driving chips DIC may provide the data voltage to the pixels PX. For example, each of the driving chips DIC may be a data driving part.

The driving chips DIC may be combined on the display panel DP (e.g., first substrate SUB1). For example, as illustrated in FIGS. 1 and 2, the driving chips DIC may be directly mounted using chip-on-glass (COG) or chip-on-plastic (COP) method in the pad area PA of the display panel DP (e.g., first substrate SUB1).

The display panel DP may include pad electrodes PE. The pad electrodes PE may be disposed in the pad area PA on the first substrate SUB1. For example, the pad electrodes PE may be located in the first direction DR1 from the display area DA. In an embodiment of the present disclosure, the pad electrodes PE may be arranged along the second direction DR2. The pad electrodes PE may be electrically connected to the driving chips DIC and the circuit board CB.

In a plan view, the pad electrodes PE and the driving chips DIC may be arranged in parallel along the second direction DR2. In an embodiment of the present disclosure, the pad electrodes PE may be disposed between the driving chips DIC on a plane. For example, the pad electrodes PE may be arranged along the second direction DR2 from one of the driving chips DIC, and the pad electrodes PE may be arranged along the second direction DR2 from one of the driving chips DIC.

The pad electrodes PE may not overlap with the driving chips DIC in the first direction DR1. For example, the pad electrodes PE may not be disposed along the first direction DR1 from the driving chips DIC. For example, in a plan view, the pad electrodes PE may not be disposed below the driving chips DIC, but may be disposed on the left and/or right side of each of the driving chips DIC. For example, the pad electrodes PE may be spaced apart from and arranged away from the driving chips DIC along the second direction DR2.

The pad electrodes PE may include a conductive material. Examples of the conductive materials that can be used as pad electrodes PE may include metals, alloys, metal nitrides, conductive metal oxides, transparent conductive materials, etc. The conductive materials can be used alone or in a combination thereof.

The display device DD may further include connection wiring disposed in the pad area PA. The connection wiring may electrically connect driving chips DIC with pad electrodes PE.

The circuit board CB may be disposed in the pad area PA on the substrate SUB. For example, the circuit board CB may overlap a portion of the pad area PA. One end of the circuit board CB may be electrically connected to the pad electrodes PE. Accordingly, the circuit board CB may be electrically connected to the driving chips DIC through the pad electrodes PE and the connection wiring. The circuit board CB may be directly coupled to the pad electrodes PE. Accordingly, dead space of the display device DD may be reduced. Also, the manufacturing process of the display device DD can be simplified. Also, the manufacturing cost of the display device DD can be reduced.

At least a portion of the circuit board CB may overlap the driving chips DIC along the second direction DR2. For example, the pad electrodes PE may be arranged in parallel with the driving chips DIC along the second direction DR2, and accordingly, at least a portion of the circuit board CB coupled to the pad electrodes PE may overlap the driving chips DIC along the second direction DR2. For example, the portion of the circuit board CB coupled to the pad electrodes PE may be disposed on the left and/or right side of each of the driving chips DIC.

The circuit board CB may be electrically connected to an external device. The circuit board CB may generate a scan control signal, a data control signal, and image data using an image signal and a plurality of timing signals input from the external device, and the generated scan control signal and the data control signal, and the image data may be provided to driving chips DIC. In an embodiment of the present disclosure, the circuit board CB may be a printed circuit board (PCB).

As illustrated in FIGS. 2, 4, and 5, the circuit board CB may include a base substrate BS and leading electrodes LE.

In an embodiment of the present disclosure, the base substrate BS may be a rigid substrate. For example, the base substrate BS may not be substantially flexible. In this case, the circuit board CB may be rigid. In an embodiment of the present disclosure, the base substrate BS may be a flexible substrate. For example, the base substrate BS may be flexible so that the circuit board CB may be flexible.

The leading electrodes LE may be disposed on a surface of the base substrate BS facing the display panel DP. The leading electrodes LE may be electrically connected to the pad electrodes PE. Each of the leading electrodes LE may overlap the pad electrodes PE in a plan view. For example, the leading electrodes LE may be arranged to correspond to the pad electrodes PE in a plan view. In an embodiment of the present disclosure, the leading electrodes LE may be arranged along the second direction DR2.

In a plan view, the leading electrodes LE and driving chips DIC may be arranged in parallel along the second direction DR2. In an embodiment of the present disclosure, the leading electrodes LE may be disposed between the driving chips DIC in a plan view. For example, the leading electrodes LE may be located in the second direction DR2 from one of the driving chips DIC, and the leading electrodes LE may be located in a direction opposite to the second direction DR2 from one of the other driving chips DIC.

The leading electrodes LE may not overlap with the driving chips DIC in the first direction DR1. For example, the leading electrodes LE may not be disposed in the first direction DR1 from the driving chips DIC. For example, in a plan view, the leading electrodes LE may not be disposed below the driving chips DIC, but may be disposed on the left and/or right side of each of the driving chips DIC. For example, the leading electrodes LE may be spaced apart from and arranged away from the driving chips DIC along the second direction.

The leading electrodes LE may include a conductive material. Examples of the conductive materials that can be used as leading electrodes LE may include metals, alloys, metal nitrides, conductive metal oxides, transparent conductive materials, etc. The conductive materials can be used alone or in combination with each other.

The circuit board CB may be coupled to the pad electrodes PE through an adhesive film ACF. For example, the leading electrodes LE of the circuit board CB may be coupled to the pad electrodes PE through the adhesive film ACF. For example, the adhesive film ACF may be disposed between the pad electrodes PE and the leading electrodes LE.

The adhesive film ACF may include an adhesive member RS and conductive balls CDB dispersed within the adhesive member RS. The circuit board CB may be coupled to the pad area PA on the first board SUB1 by an adhesive member RS, and may be electrically connected to the pad electrodes PE by the conductive balls CDB interposed between the pad electrodes PE and the leading electrodes LE.

The adhesive member RS may include an insulating adhesive material. For example, the adhesive member RS may include a thermosetting resin, an ultraviolet curing resin, a thermoplastic resin, etc. Each of the conductive balls CDB may include a conductive material. For example, each of the conductive balls CDB may include polymer particles and a metal coating layer that coats the polymer particles. However, the present disclosure is not necessarily limited thereto, and the conductive balls CDB may include conductive nanowires or conductive paste.

In a plan view, the adhesive film ACF and the driving chips DIC may be arranged in parallel along the second direction DR2. In an embodiment of the present disclosure, the adhesive film ACF may be disposed between the driving chips DIC in a plan view. For example, the adhesive film ACF may be located in the second direction DR2 from one of the driving chips DIC, and the adhesive film ACF may be located in a direction opposite to the second direction DR2 from the another driving chip among the driving chips DIC.

The adhesive film ACF may not overlap the driving chips DIC in the first direction DR1. For example, the adhesive film ACF may not be disposed in the first direction DR1 from the driving chips DIC. For example, in a plan view, the adhesive film ACF may not be disposed below the driving chips DIC, but may be disposed on the left and/or right side of each of the driving chips DIC. For example, the adhesive film ACF may be spaced apart from and arranged away from the driving chip DIC along the second direction DR2.

In the process of coupling the circuit board CB to the pad area PA on the first substrate SUB1, a bonding tool may be used. The bonding tool may be a thermal compression bonding device that provides heat and pressure. The bonding tool may provide heat and pressure in a direction opposite to the third direction DR3. For example, the bonding tool may provide heat and pressure towards the first substrate SUB1. When pressed using the bonding tool, the pad electrodes PE and the leading electrodes LE may be bonded to each other by the adhesive film ACF, and the conductive balls CDB may electronically connect the pad electrodes PE with the leading electrodes LE.

To use the bonding tool, space may be required so that the bonding tool may be applied onto the first substrate SUB1 without interfering with the driving chips DIC. In the display device DD according to an embodiment of the present disclosure, the pad electrodes PE coupled to the circuit board CB may not be disposed below the driving chips DIC in a plan view, but may be placed on the left and/or right side of each of the driving chips DIC. For example, a space for applying the bonding tool onto the first substrate SUB1 without interfering with the driving chips DIC may be formed on the left and/or right side of each of the driving chips DIC, and a separate space for applying the bonding tool on the first substrate SUB1 may not be formed below the driving chips DIC. Accordingly, the width of the pad area PA in the first direction DR1 may be reduced. For example, the dead space of the display device DD can be reduced. Accordingly, visibility of the display device DD can increase.

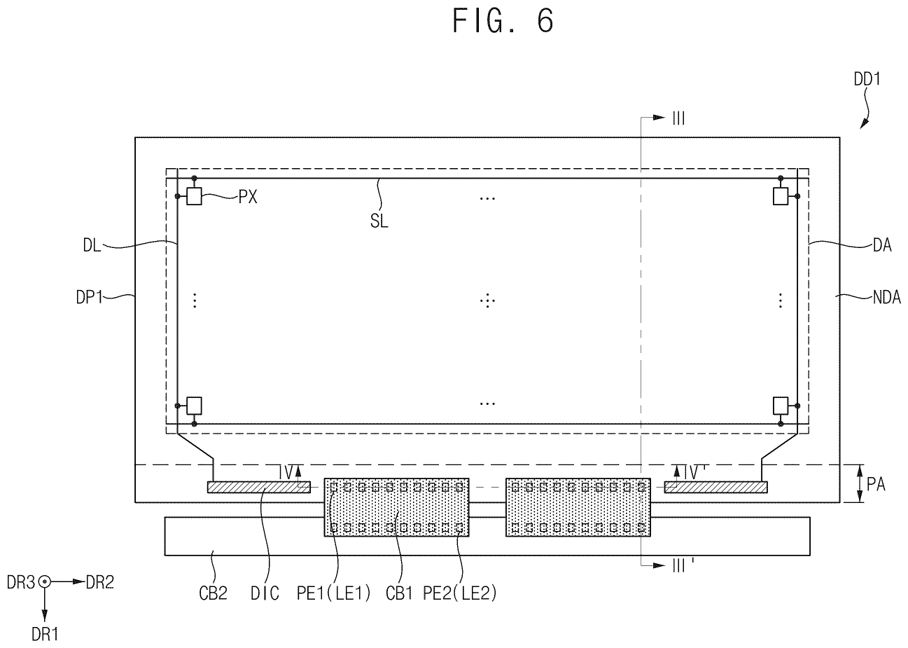

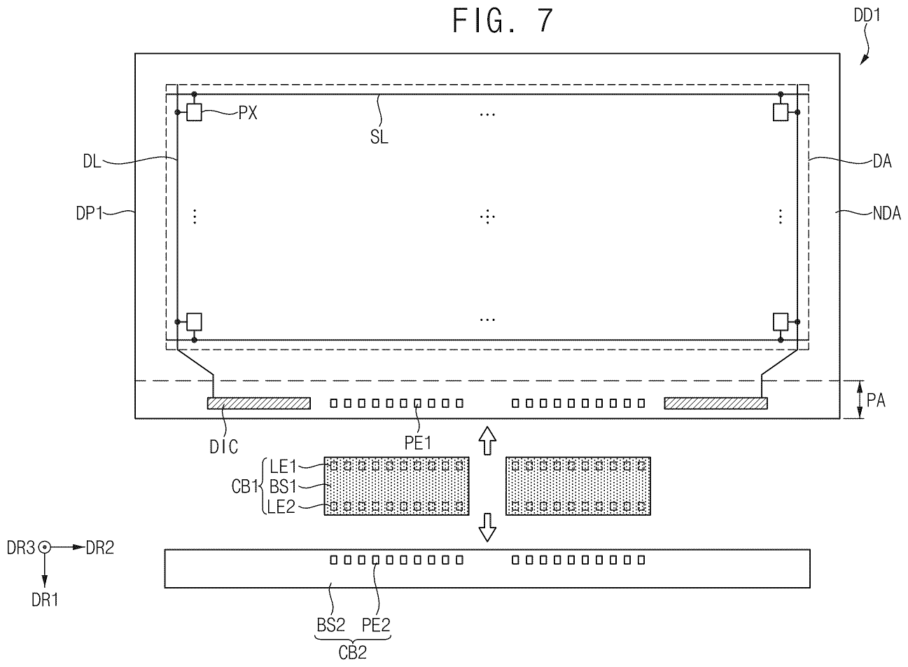

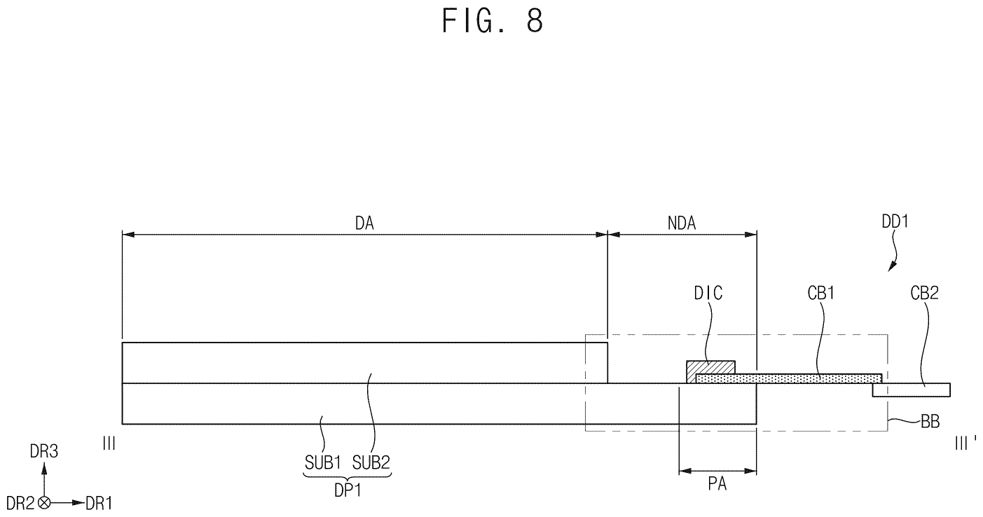

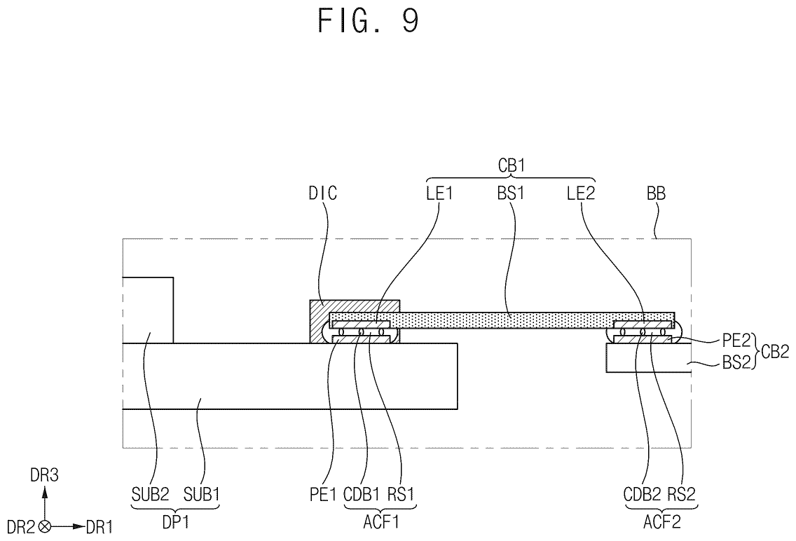

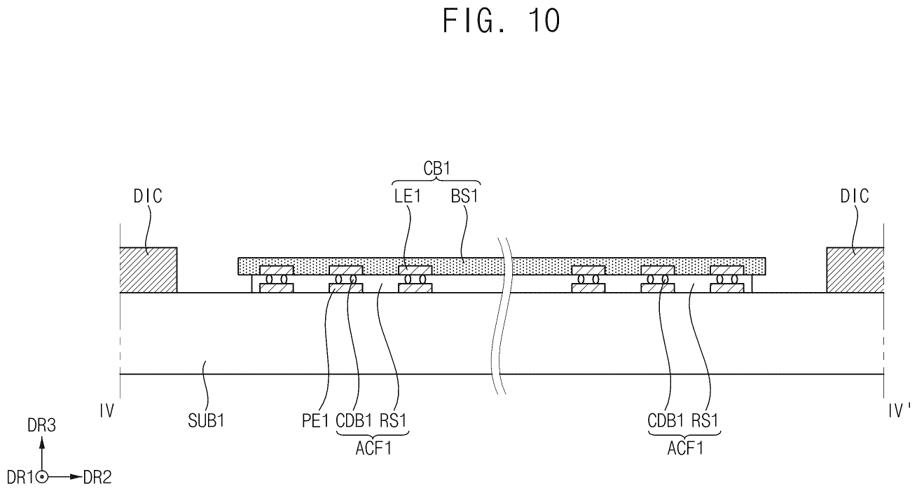

FIG. 6 is a plan view illustrating a display device according to an embodiment of the present disclosure. FIG. 7 is a plan view illustrating the display panel of FIG. 6, the first circuit boards, and the second circuit board before they are combined. FIG. 8 is a cross-sectional view taken along line III-III′ of FIG. 6. FIG. 9 is an enlarged view showing the area BB of FIG. 8. FIG. 10 is a cross-sectional view taken along line IV-IV of FIG. 6.

Referring to FIGS. 6 to 10, the display device DD1 according to an embodiment of the present disclosure may include a display panel DP1, driving chips DIC, first circuit boards CB1, and a second circuit board CB2.

The display panel DP1 of FIGS. 6 to 10 may be substantially the same as the display panel DP of FIGS. 1 to 5, except that the display panel DP1 of FIGS. 6 to 10 includes first pad electrodes PE1 instead of the pad electrodes PE (see FIG. 1). To the extent that an element has not been described in detail, it may be assumed that the element is at least similar to corresponding elements that have been described in FIGS. 1 to 5.

Also, the description of the driving chips DIC described with reference to FIGS. 1 to 5 may be applied equally to the driving chips DIC of FIGS. 6 to 10.

The display panel DP1 may include first pad electrodes PE1. The first pad electrodes PE1 may be disposed in the pad area PA on the first substrate SUB1. For example, the first pad electrodes PE1 may be located in the first direction DR1 from the display area DA. In an embodiment of the present inventive concept, the first pad electrodes PE1 may be arranged along the second direction DR2. The first pad electrodes PE1 may be electrically connected to the driving chips DIC, the first circuit boards CB1, and the second circuit boards CB2.

In a plan view, the first pad electrodes PE1 and the driving chips DIC may be arranged in parallel along the second direction DR2. In an embodiment of the present inventive concept, the first pad electrodes PE1 may be disposed between the driving chips DIC on a plane. For example, the first pad electrodes PE1 may be located in the second direction DR2 from one of the driving chips DIC, and the first pad electrodes PE1 may be located in a direction opposite to the second direction DR2 from one of the driving chips DIC.

The first pad electrodes PE1 may not overlap with the driving chips DIC in the first direction DR1. For example, the first pad electrodes PEL may not be disposed in the first direction DR1 from the driving chips DIC. For example, in a plan view, the first pad electrodes PE1 may not be disposed below the driving chips DIC, but may be disposed on the left and/or right side of each of the driving chips DIC.

The first pad electrodes PE1 may include a conductive material. Examples of the conductive materials that can be used as first pad electrodes PE1 may include metals, alloys, metal nitrides, conductive metal oxides, transparent conductive materials, etc. The conductive materials can be used alone or in combination with each other.

The display device DD1 may further include connection wiring disposed in the pad area PA. The connection wiring may electrically connect driving chips DIC with the first pad electrodes PE1.

The first circuit boards CB1 may be disposed in the pad area PA on the substrate SUB. For example, the first circuit boards CB1 may overlap a portion of the pad area PA. Each end of the first circuit boards CB1 may be electrically connected to the first pad electrodes PE1. Accordingly, the first circuit boards CB1 may be electrically connected to the driving chips DIC through the first pad electrodes PEL and the connection wiring. The first circuit boards CB1 may be directly coupled to the first pad electrodes PE1.

At least a portion of the first circuit boards CB1 may overlap the driving chips DIC along the second direction DR2. For example, the first pad electrodes PE1 may be arranged in parallel with the driving chips DIC along the second direction DR2, and accordingly, at least a portion of each of the first circuit boards CB1 coupled to the first pad electrodes PEL may overlap the driving chips DIC along the second direction DR2.

The other end of each of the first circuit boards CB1 may be electrically connected to a second circuit board CB2. The second circuit board CB2 may be electrically connected to an external device. The second circuit board CB2 may generate a scan control signal, a data control signal, and image data using an image signal and a plurality of timing signals input from the external device, and the generated scan control signal and the data control signal, and the image data may be provided to the driving chips DIC through the first circuit boards CB1. In an embodiment of the present disclosure, the second circuit board CB2 may be a printed circuit board (PCB).

As illustrated in FIGS. 6, 7, 9, and 10, each of the first circuit boards CB1 may include a first base board BS1 and first leading electrodes LE1.

In an embodiment of the present disclosure, the first base substrate BS1 may be a flexible substrate. For example, the first base substrate BS1 may have flexibility. In this case, the first circuit boards CB1 may be flexible. In an embodiment of the present disclosure, the first base substrate BS1 may be a rigid substrate. For example, the first base substrate BS1 may not be substantially flexible. In this case, the first circuit boards CB1 may be rigid.

The first leading electrodes LE1 may be disposed on one side of the first base substrate BS1 facing the display panel DP1. The first leading electrodes LE1 may be electrically connected to the first pad electrodes PE1. The first leading electrodes LE1 may each overlap the first pad electrodes PE1 in a plan view. For example, the first leading electrodes LE1 may be arranged to correspond to the first pad electrodes PE1 in a plan view. In an embodiment of the present disclosure, the first leading electrodes LE1 may be arranged along the second direction DR2. For example, each of the first leading electrodes LE1 may be disposed next to each other along the horizontal line.

In a plan view, the first leading electrodes LE1 and the driving chips DIC may be arranged in parallel along the second direction DR2. In an embodiment of the present disclosure, the first leading electrodes LE1 may be disposed between the driving chips DIC in a plan view. For example, the first leading electrodes LE1 may be located in the second direction DR2 from one of the driving chips DIC, and the first leading electrodes LE1 may be located in a direction opposite to the second direction DR2 from one of the driving chips DIC.

The first leading electrodes LE1 may not overlap with the driving chips DIC in the first direction DR1. For example, the first leading electrodes LE1 may not be disposed in the first direction DR1 from the driving chips DIC. For example, in a plan view, the first leading electrodes LE1 may not be disposed below the driving chips DIC, but may be disposed on the left and/or right side of each of the driving chips DIC.

The first leading electrodes LE1 may include a conductive material. Examples of the conductive materials that can be used as the first leading electrodes LE1 may include metals, alloys, metal nitrides, conductive metal oxides, transparent conductive materials, etc. The conductive materials can be used alone or in combination with each other.

The first circuit boards CB1 may be coupled to the first pad electrodes PE1 through the first adhesive film ACF1. For example, the first leading electrodes LE1 of the first circuit boards CB1 may be coupled to the first pad electrodes PEL through the first adhesive film ACF1. For example, the first adhesive film ACF1 may be disposed between the first pad electrodes PE1 and the first leading electrodes LE1.

The first adhesive film ACF1 may include a first adhesive member RS1 and first conductive balls CDB1 distributed within the first adhesive member RS1. The first circuit boards CB1 may be coupled to the pad area PA on the first substrate SUB1 by a first adhesive member RS1, and may be electrically connected to the first pad electrodes PEL by the first conductive balls CDB1 interposed between the first pad electrodes PE1 and the first leading electrodes LE1.

The first adhesive member RS1 may include an insulating adhesive material. For example, the first adhesive member RS1 may include a thermosetting resin, an ultraviolet curing resin, a thermoplastic resin, etc. Each of the first conductive balls CDB1 may include a conductive material. For example, each of the first conductive balls CDB1 may include polymer particles and a metal coating layer that coats the polymer particles. However, the present disclosure is not necessarily limited thereto, and each of the first conductive balls CDB1 may be a nanowire or conductive paste that is made of a conductive material.

In a plan view, the first adhesive film ACF1 and the driving chips DIC may be arranged in parallel along the second direction DR2. In an embodiment of the present disclosure, the first adhesive film ACF1 may be disposed between the driving chips DIC in a plan view. For example, the first adhesive film ACF1 may be located in the second direction DR2 from one of the driving chips DIC, and the first adhesive film ACF1 may be located in the second direction DR2 from one of the driving chips DIC.

The first adhesive film ACF1 may not overlap the driving chips DIC in the first direction DR1. For example, the first adhesive film ACF1 may not be disposed in the first direction DR1 from the driving chips DIC. For example, in a plan view, the first adhesive film ACF1 may not be disposed below the driving chips DIC, but may be disposed on the left and/or right side of each of the driving chips DIC.

As illustrated in FIGS. 6, 7, 9, and 10, the second circuit board CB2 may include a second base board BS2 and second pad electrodes PE2. Also, the first circuit boards CB1 may further include second leading electrodes LE2.

In an embodiment of the present disclosure, the second base substrate BS2 may be a rigid substrate. For example, the second base substrate BS2 ay not have substantially flexibility. In this case, the second circuit board CB2 may be rigid. In an embodiment of the present disclosure, the second base substrate BS2 may be a flexible substrate. For example, the second base substrate BS2 may have flexibility. In this case, the second circuit board CB2 may be flexible.

The second pad electrodes PE2 may be disposed on one side of the second base board BS2 facing the first circuit boards CB1. In an embodiment of the present disclosure, the second pad electrodes PE2 may be arranged along the second direction DR2. The second pad electrodes PE2 may be electrically connected to the first circuit boards CB1.

The second pad electrodes PE2 may include a conductive material. Examples of the conductive materials that can be used as second pad electrodes PE2 may include metals, alloys, metal nitrides, conductive metal oxides, transparent conductive materials, etc. The conductive materials can be used alone or in combination with each other.

The second leading electrodes LE2 may be disposed on one side of the first base board BS1 facing the second circuit board CB2. For example, the second leading electrodes LE2 may be disposed on an opposite side of the first base board BS1 where the first leading electrodes are disposed. The second leading electrodes LE2 may be electrically connected to the second pad electrodes PE2. Each of the second leading electrodes LE2 may overlap the second pad electrodes PE2 in a plan view. For example, the second leading electrodes LE2 may be arranged to correspond to the second pad electrodes PE2 in a plan view. In an embodiment of the present disclosure, the second leading electrodes LE2 may be arranged along the second direction DR2.

The first circuit boards CB1 may be coupled to the second pad electrodes PE2 through the second adhesive film ACF2. For example, the second leading electrodes LE2 of the first circuit boards CB1 may be coupled to the second pad electrodes PE2 through the second adhesive film ACF2. For example, the second adhesive film ACF2 may be disposed between the second pad electrodes PE2 and the second leading electrodes LE2.

The second adhesive film ACF2 may include a second adhesive member RS2 and second conductive balls CDB2 distributed within the second adhesive member RS2. The first circuit boards CB1 may be coupled to the second circuit board CB2 by a second adhesive member RS2, and may be electrically connected to the second pad electrodes PE2 by the conductive balls CDB2 interposed between the second pad electrodes PE2 and the second leading electrodes LE2.

The second adhesive member RS2 may include an insulating adhesive material. For example, the second adhesive member RS2 may include a thermosetting resin, an ultraviolet curing resin, a thermoplastic resin, etc. Each of the second conductive balls CDB2 may include a conductive material. For example, each of the second conductive balls CDB2 may include polymer particles and a metal coating layer that coats the polymer particles. However, the present disclosure is not necessarily limited thereto, and each of the first conductive balls CDB1 may be a nanowire or conductive paste that is made of a conductive material.

In the process of bonding the first circuit boards CB1 to the pad area PA on the first board SUB1, the bonding tool may be used. When compressed using the bonding tool, the first pad electrodes PEL and the first leading electrodes LE1 may be bonded to each other by the first adhesive film ACF1, and the first conductive balls CDB1 may electrically connect the first pad electrodes PE1 with the first leading electrodes LE1.

In the display device DD according to an embodiment of the present disclosure, the first pad electrodes PE1 coupled to the first circuit boards CB1 may not be disposed below the driving chips DIC in a plan view, but may be placed on the left and/or right side of each of the driving chips DIC. For example, a space for applying the bonding tool onto the first substrate SUB1 without interfering with the driving chips DIC may be formed on the left and/or right side of each of the driving chips DIC, and a separate space for applying the bonding tool to the first substrate SUB1 may not be formed below the driving chips DIC. Accordingly, the width of the pad area PA in the first direction DR1 may be reduced. For example, the dead space of the display device DD1 can be reduced. Accordingly, visibility of the display device DD1 can be improved.

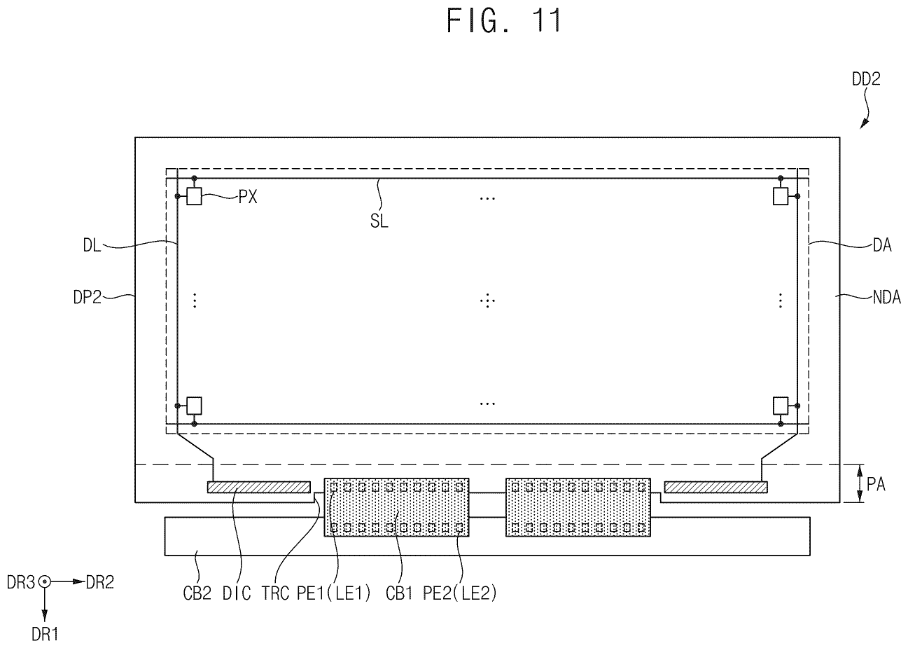

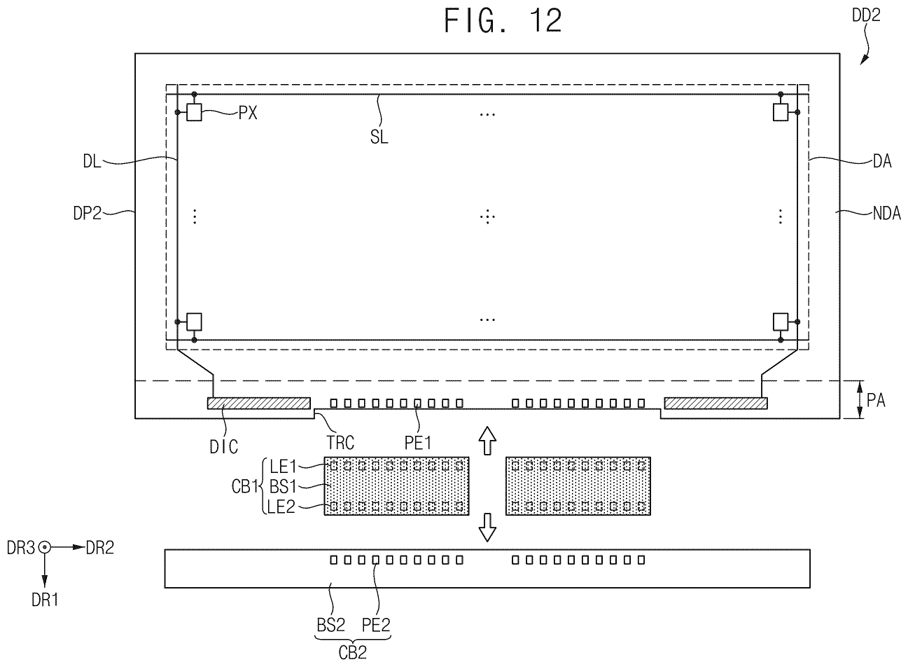

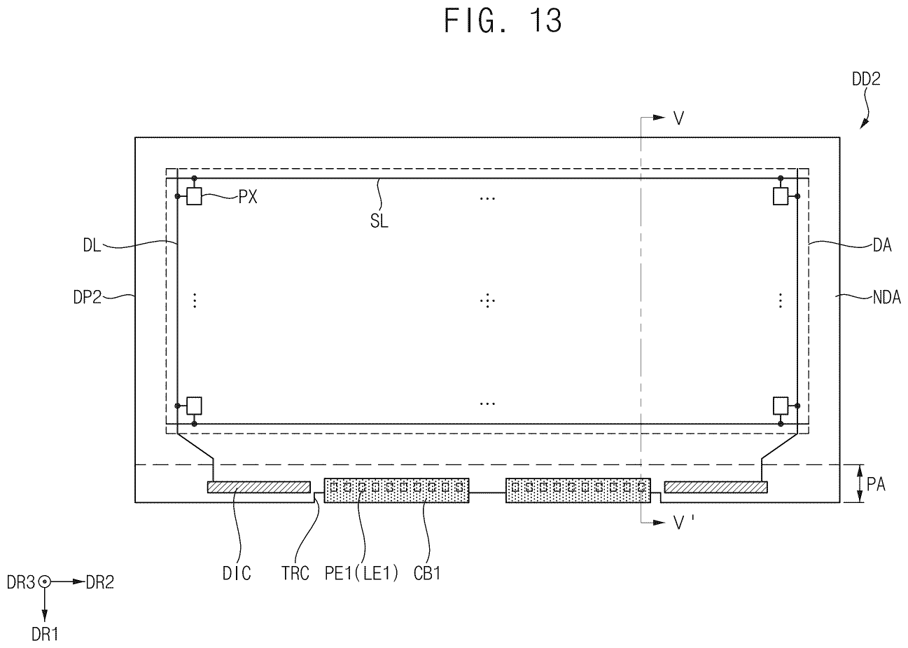

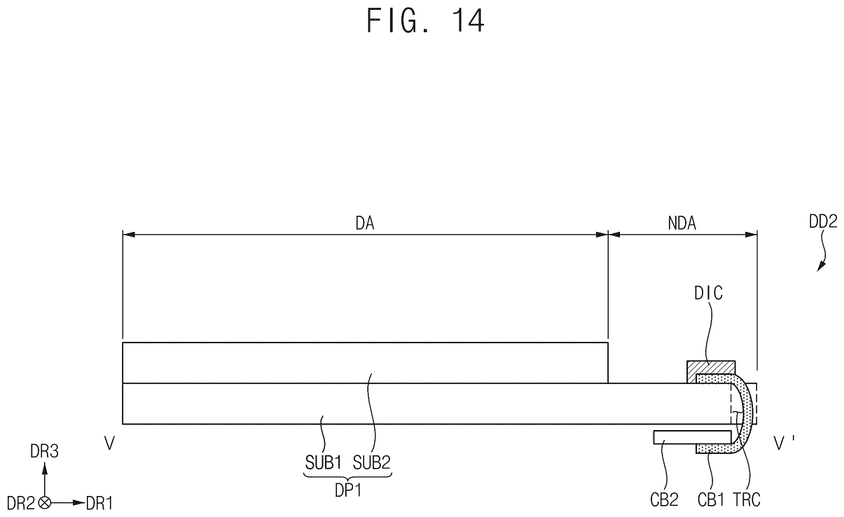

FIG. 11 is a plan view illustrating a display device according to an embodiment of the present disclosure. FIG. 12 is a plan view illustrating the display panel, the first circuit boards, and the second circuit board of FIG. 11 before they are coupled. FIG. 13 is a plan view showing the first circuit board of FIG. 11 bent. FIG. 14 is a cross-sectional view taken along line V-V of FIG. 13.

Referring to FIGS. 11 to 14, the display device DD2 according to an embodiment of the present disclosure may include a display panel DP2, driving chips DIC, first circuit boards CB1, and a second circuit board CB2.

The display panel DP2 of FIGS. 11 to 14 may be substantially the same as the display panel DP1 of FIGS. 6 to 10 except that the first substrate SUB1 defines the trench TRC. To the extent that an element has not been described in detail, it may be assumed that the element is at least similar to corresponding elements that have been described in FIGS. 6 to 10.

In an embodiment of the present disclosure, at least a portion of the first substrate SUB1 may be recessed to define a trench TRC. For example, a portion of the long side of the first substrate SUB1 extending along the second direction DR2 in the first direction DR1 may be depressed in the direction opposite to the first direction DR1 to define a trench TRC. For example, the trench TRC may be defined in the pad area PA.

The trench TRC may be located in the first direction DR1 from the first pad electrodes PE1. At least a portion of each of the first circuit boards CB1 may overlap the trench TRC in a plan view. For example, as illustrated in FIGS. 13 and 14, in an embodiment of the present disclosure, the flexible first circuit boards CB1 may be bent so that the second circuit board CB2 is located below the display panel DP2. In this case, at least a portion of each of the first circuit boards CB1 may be located within the trench TRC. For example, the first circuit boards CB1 may be bent through the space defined by the trench TRC.

According to an embodiment of the present disclosure, in which the first substrate SUB1 defines the trench TRC, the curvature part formed by bending the first circuit boards CB1 may be located within the space defined by the trench TRC. Accordingly, the curvature part may not protrude in the first direction DR1 beyond the long side of the first substrate SUB1. Accordingly, the overall width of the display device DD2 in the first direction DR1 may be reduced. For example, the dead space of the display device DD2 can be further reduced. Accordingly, the visibility of the display device DD2 can be further improved.

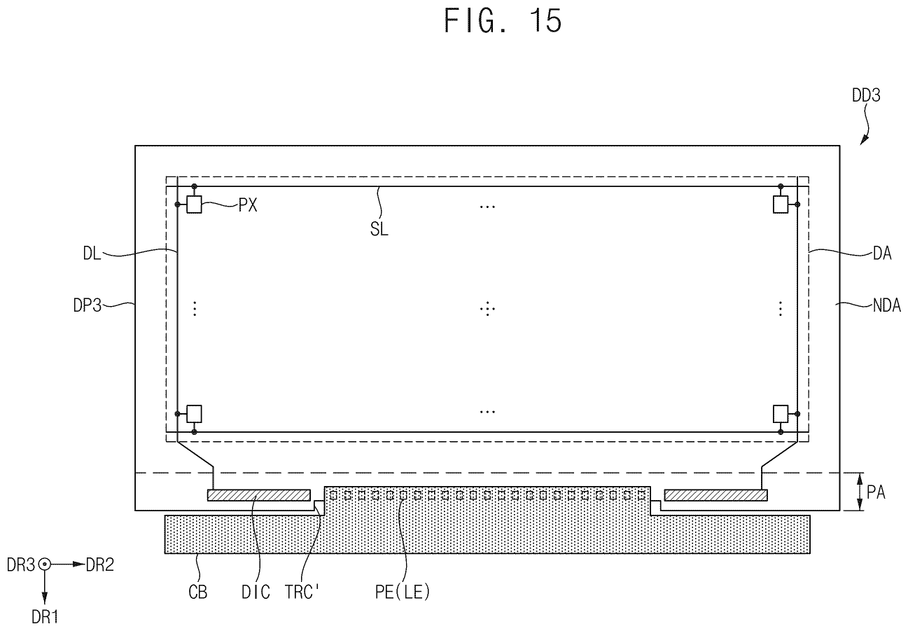

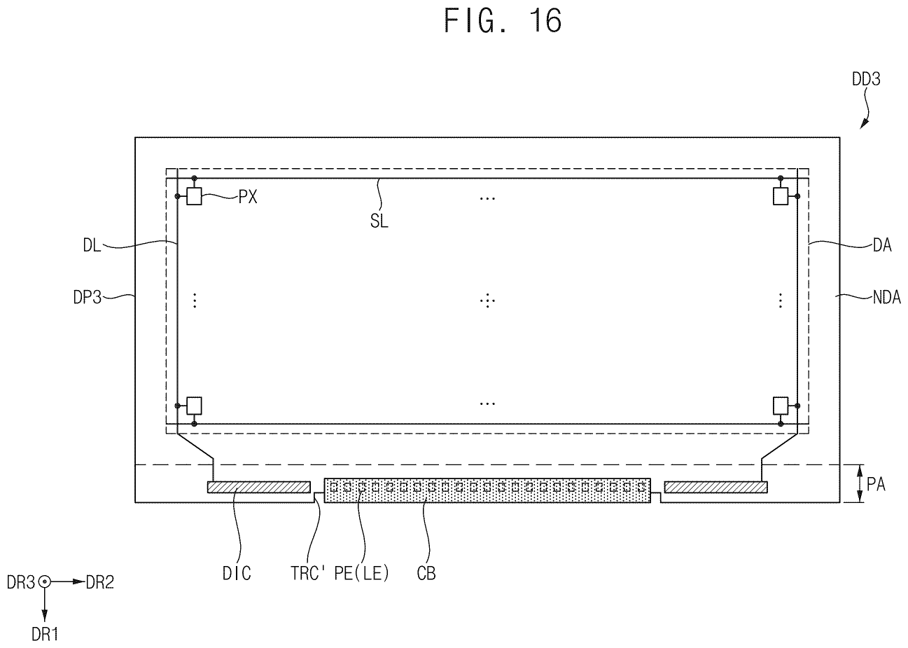

FIG. 15 is a plan view illustrating a display device according to an embodiment of the present disclosure. FIG. 16 is a plan view showing the circuit board of FIG. 15 bent.

Referring to FIGS. 15 and 16, the display device DD3 according to an embodiment of the present disclosure may include a display panel DP3, driving chips DIC, and a circuit board CB.

The display panel DP3 of FIGS. 15 and 16 may be substantially the same as the display panel DP of FIGS. 1 to 5 except that the first substrate SUB1 defines the trench TRC′. To the extent that an element has not been described in detail, it may be assumed that the element is at least similar to corresponding elements that have been described in FIGS. 1 to 5.

In an embodiment of the present disclosure, at least a portion of the first substrate SUB1 may be depressed and define a trench TRC′. For example, a portion of the long side of the first direction DR1 extending along the second direction DR2 of the first substrate SUB1 may be depressed in the opposite direction of the first direction DR1 to define a trench TRC″. For example, the trench TRC′ may be defined in the pad area PA.

The trench TRC′ may be located in the first direction DR1 from the pad electrodes PE. At least a portion of the circuit board CB may overlap the trench TRC′ in a plan view. For example, in an embodiment of the present disclosure, when the flexible circuit board CB is bent so that a portion of the circuit board CB is located below the display panel DP3, at least a portion of the circuit board CB may be located in the trench TRC′. For example, the circuit board CB may be bent through the space defined by the trench TRC′.

According to an embodiment of the present disclosure, in which the first substrate SUB1 defines the trench TRC′, the curvature part formed by bending the circuit board CB may be located within the space defined by the trench TRC. Accordingly, the curvature part may not protrude in the first direction DR1 beyond the long side of the first substrate SUB1 in the first direction DR1. Accordingly, the overall width of the display device DD3 in the first direction DR1 may be reduced. For example, the dead space of the display device DD3 can be further reduced. Accordingly, the visibility of the display device DD3 can be further improved.

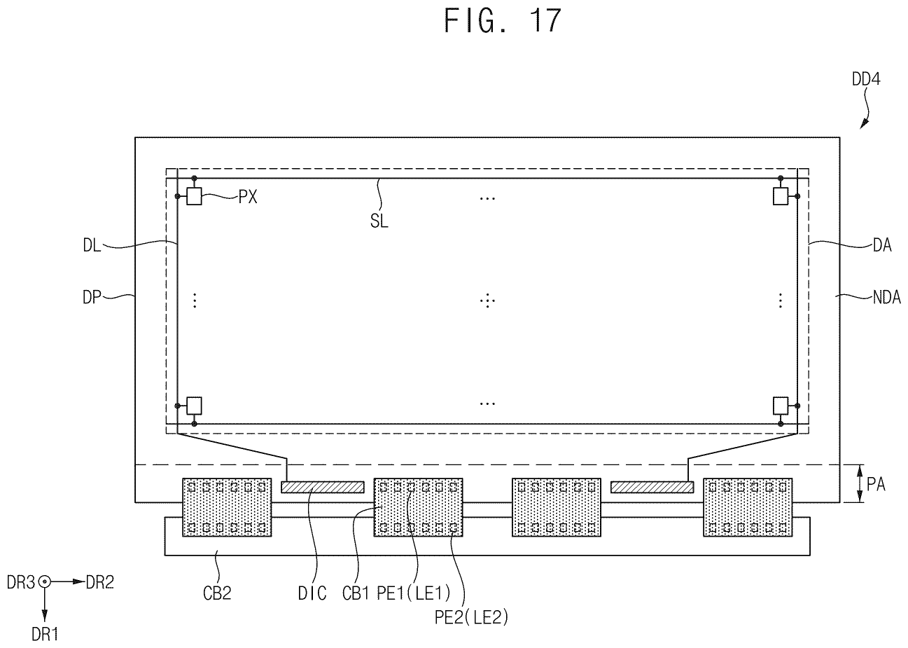

FIG. 17 is a plan view illustrating a display device according to an embodiment of the present disclosure.

Referring to FIG. 17, the display device DD4 according to an embodiment of the present disclosure may include a display panel DP, driving chips DIC, first circuit boards CB1, and second circuit boards CB2.

In the display device DD4 according to an embodiment of the present disclosure, at least some of the first pad electrodes PE1 may be located on both sides along the second direction DR2 with respect to one of the driving chips DIC. For example, the first pad electrodes PE1 may be located on both the left and right sides of each of the driving chips DIC in a plan view.

For example, some of the first pad electrodes PE1 may be located in the second direction DR2 from one of the driving chips DIC, and other part of the first pad electrodes PE1 may be located in a direction opposite to the second direction DR2 from the driving chip DIC. Also, another part of the first pad electrodes PE1 may be located in the second direction DR2 from another driving chip of the driving chips DIC, and another part of the first pad electrodes PE1 may be located in a direction opposite to the second direction DR2 from the driving chip DIC. For example, the driving chips DIC may be disposed between the first pad electrodes PE1 along the second direction DR2.

In the display device DD4 according to one embodiment of the present disclosure, corresponding to the arrangement of the first pad electrodes PE1, at least some of the first circuit boards CB1 may be located on both sides along the second direction DR2 with respect to one of the driving chips DIC. For example, the first circuit boards CB1 may be located on both the left and right sides of each of the driving chips DIC in a plan view.

Likewise, corresponding to the arrangement of the first pad electrodes PE1, at least some of the first leading electrodes LE1 may be located on both sides along the second direction DR2 with respect to one of the driving chips DIC. For example, the first leading electrodes LE1 may be located on both the left and right sides of each of the driving chips DIC in a plan view.

According to an embodiment of the present disclosure, in which the first pad electrodes PE1 are located on both the left and right sides of each of the driving chips DIC in a plan view, design of the connection wiring connecting the driving chips DIC and the first pad electrodes PE1 may be easier. For example, the connection wiring may be easily designed without increasing the width of the pad area PA in the first direction DR1. For example, the dead space of the display device DD4 can be further reduced. Accordingly, the visibility of the display device DD4 can be further improved.

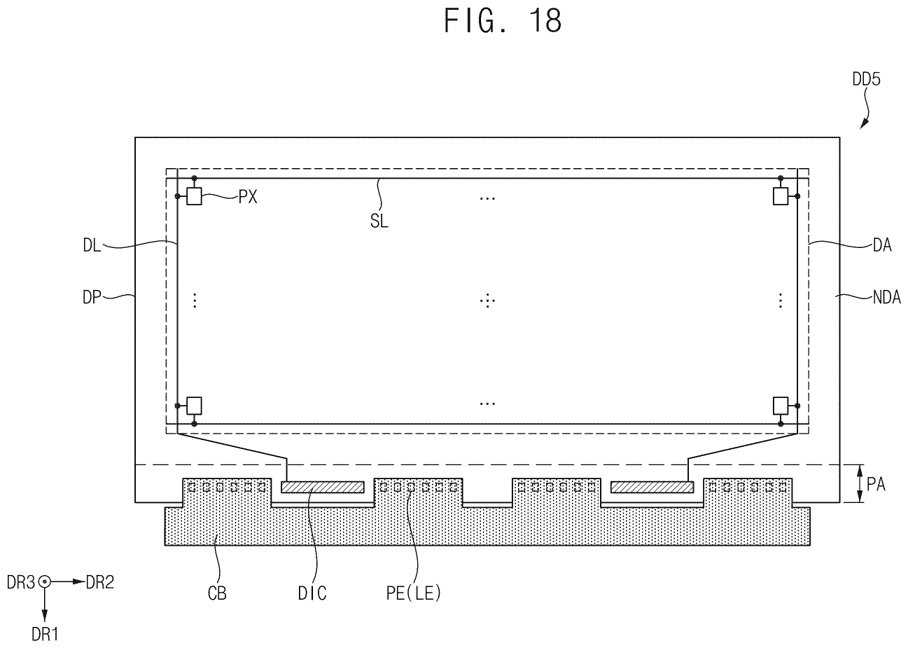

FIG. 18 is a plan view illustrating a display device according to an embodiment of the present disclosure.

Referring to FIG. 18, the display device DD5 according to an embodiment of the present disclosure may include a display panel DP, driving chips DIC, and a circuit board CB″.

In the display device DD5 according to one embodiment of the present disclosure, at least some of the pad electrodes PE may be located on both sides along the second direction DR2 with respect to one of the driving chips DIC. For example, the pad electrodes PE may be located on both the left and right sides of each of the driving chips DIC in a plan view.

For example, some of the pad electrodes PE may be located in the second direction DR2 from one of the driving chips DIC, and other part of the pad electrodes PE may be located in a direction opposite to the second direction DR2 from the driving chip DIC. Also, another part of the pad electrodes PE may be located in the second direction DR2 from one of the driving chips DIC, and another part of the pad electrodes PE may be located in a direction opposite to the second direction DR2 from the driving chip DIC. For example, the pad electrodes PE may be disposed between the driving chips DIC along the second direction DR2.

In the display device DD5 according to an embodiment of the present disclosure, corresponding to the arrangement of the pad electrodes PE, portions of the circuit board CB may be located on both sides of the second direction DR2 with respect to one of the driving chips DIC. For example, the portions of the circuit board CB may be located on both the left and right sides of each of the driving chips DIC in a plan view.

Likewise, corresponding to the arrangement of the pad electrodes PE, at least some of the leading electrodes LE may be located on both sides of the second direction DR2 with respect to one of the driving chips DIC. For example, the leading electrodes LE may be located on both the left and right sides of each of the driving chips DIC in a plan view.

According to an embodiment of the present disclosure, in which the pad electrodes PE are located on both the left and right sides of each of the driving chips DIC in a plan view, design of the connection wiring connecting the driving chips DIC and the pad electrodes PE may be easier. For example, the connection wiring may be easily designed without increasing the width of the pad area PA in the first direction DR1. For example, the dead space of the display device DD5 can be further reduced. Accordingly, the visibility of the display device DD5 can be further improved.

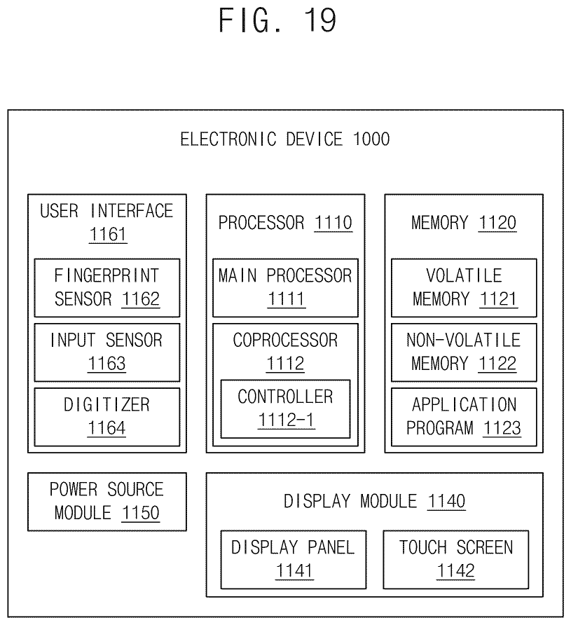

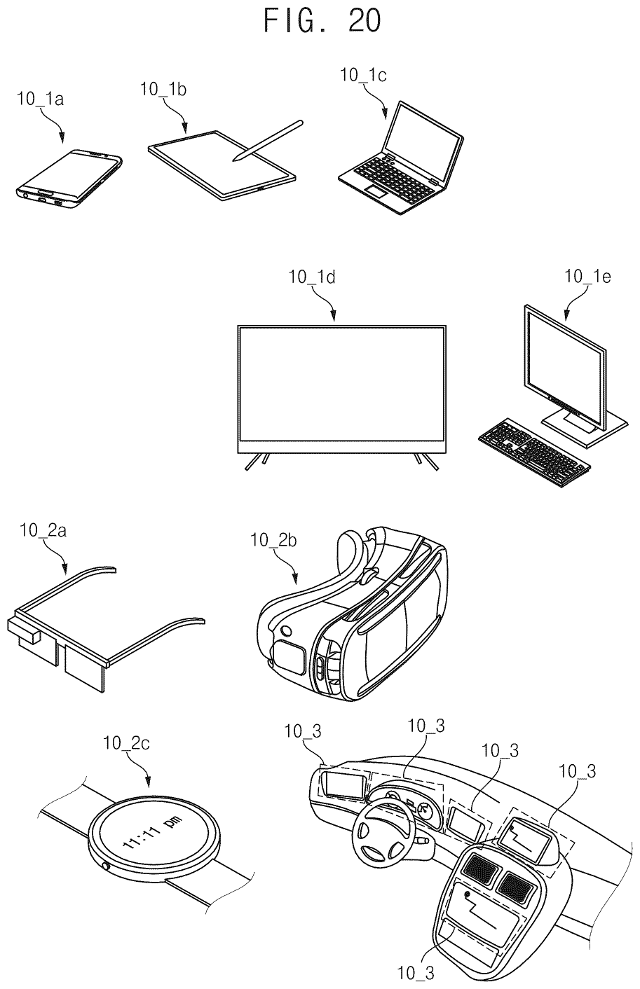

FIG. 19 is a block diagram illustrating an electronic device according to embodiments of the present disclosure. FIG. 20 are schematic diagrams illustrating an electronic device according to various embodiments.

Referring to FIG. 19, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone 10_1a, camera, smart TV, smartwatch, tablet PC 10_1b, laptop 10_1c, television 10_1d, and a desktop monitor 10_1e, or automotive display. For example, the electronic device 1000 may be a smartphone 10_1a including a touch-sensitive display area DA for interaction and a non-display area NDA including sensors and circuits for enhanced functionality. For example, the electronic device 1000 may be a television 10_1d or monitor 10_1e including a large display area DA for high-resolution video playback and a non-display area NDA incorporating driving circuits or connectivity modules for external inputs. For example, the electronic device 1000 may be a smart glasses 10_2a, a head mounted display 10_2b, smartwatch 10_2c, automotive electronic devices 10_3 including a display area DA optimized for compact and high-clarity visuals and a non-display area NDA integrating biometric sensors for health monitoring. In some cases, the electronic device 1000 may be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply an optimized power source to each of the components described above including the display module 1140.

FIG. 20 are schematic diagrams showing an electronic device according to various embodiments.

Referring to FIG. 20, various electronic devices 10 to which display devices (e.g., the display device DD of FIGS. 1 and 3, the display device DD1 of FIGS. 6 to 8, the display device DD2 of FIGS. 11 to 14, the display device DD3 of FIGS. 15 and 16, the display device DD4 of FIG. 17, or the display device DD5 of FIG. 18) according to the embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

Although the present disclosure has been described above with reference to exemplary embodiments, it will be understood that those skilled in the art can variously modify and change the present disclosure without departing from the spirit and scope of the present disclosure as defined by the following claims.

What is claimed is:

1. A display device comprising:
a substrate including a display area and a pad area disposed adjacent to a side of the display area;
a driving chip disposed in the pad area in a first direction away from the side of the display area;
a plurality of pad electrodes disposed in the pad area and arranged along a second direction perpendicular to the first direction; and
a circuit board including a plurality of leading electrodes coupled to the plurality of pad electrodes, wherein a portion of the circuit board overlaps at least a portion of the pad area of the substrate.

2. The display device of claim 1, wherein the driving chip is mounted on the substrate.

3. The display device of claim 1, wherein the plurality of pad electrodes are spaced apart from and arranged away from the driving chip along the second direction.

4. The display device of claim 1, wherein at least a portion of the circuit board overlaps the driving chip in the second direction.

5. The display device of claim 1,
further comprising an adhesive film, which is disposed between the plurality of pad electrodes and the plurality of leading electrodes, for coupling the plurality of pad electrodes to the plurality of leading electrodes.

6. The display device of claim 5, wherein in a plan view, the adhesive film and the driving chip are arranged in parallel along the second direction.

7. The display device of claim 5, wherein the adhesive film and the driving chip are spaced apart from each other in the first direction.

8. The display device of claim 1, wherein the circuit board is flexible.

9. The display device of claim 1, wherein the circuit board is rigid.

10. The display device of claim 1, wherein the substrate is depressed to define a trench, and
the trench is disposed in the first direction away from the plurality of pad electrodes.

11. The display device of claim 10, wherein the circuit board is disposed in the trench.

12. A display device comprising:
a substrate including a display area and a pad area disposed adjacent to a side of the display area;
a first driving chip and a second driving chip disposed in the pad area in a first direction away from the side of the display area;
a plurality of first pad electrodes disposed in the pad area adjacent to the first driving chip and arranged along a second direction perpendicular to the first direction;
a plurality of second pad electrodes disposed in the pad area adjacent to the second driving chip and arranged along the second direction; and
a first circuit board, wherein a portion of the first circuit board overlaps at least a portion of the pad area of the substrate and coupled to the first pad electrode.

13. The display device of claim 12, wherein at least a portion of the first circuit board overlaps the first driving chip and the second driving chip in the second direction.

14. The display device of claim 12, wherein the first circuit board is coupled to the second pad electrode.

15. The display device of claim 12, further comprising:
a second circuit board overlapping at least a portion of the pad area of the substrate and coupled to the plurality of second pad electrodes,
wherein at least a portion of the second circuit board overlaps the first driving chip and the second driving chip in the second direction, and
wherein in a plan view, the first driving chip and the second driving chip are disposed between the first circuit board and the second circuit board.

16. An electronic device comprising:
a processor;
a memory having stored application programs for execution by the processor;
a display device, comprising:
a substrate including a display area and a pad area disposed adjacent to a side of the display area;
a driving chip disposed in the pad area in a first direction away from the side of the display area;
a plurality of pad electrodes disposed in the pad area and arranged along a second direction perpendicular to the first direction;
a circuit board, wherein a portion of the circuit board overlaps at least a portion of the pad area of the substrate and coupled to the pad electrode; and
an user interface configured to sense user input via touch or cursor select of an icon presented on an display panel, wherein the processor is caused to execute one or more of the stored application programs upon receipt of the user input.

17. The electronic device of claim 16, wherein the stored application programs include one or more of a camera application, an audiovisual streaming application, or a telephone application.

18. The electronic device of claim 16, wherein the user interface is a touch screen embedded in the display panel, wherein the touch screen includes touch sensors for sensing a touch or a tap by an user.

19. The electronic device of claim 16, wherein the user interface includes an audio sensor embedded in the display panel, wherein the audio sensor is configured to receive voice commands to cause access to one or more of the application programs.

20. The electronic device of claim 16, wherein the user interface includes sensors for sensing eye movements installed in the display panel.
